(19) United States
(12) Patent Application Publication
(10) Pub. No.: US 2011/0102206 A1
(43) Pub. Date: May 5, 2011

(54) Keyboard arrangement for a phonetic symbol inputting method for chinese characters

(75) Inventors: Ching-Hsiang Huang, Yongkang City (TW); Chi-Lin Hong, Yongkang City (TW)

(73) Assignee: Kun Shan University

(21) Appl. No.: 12/589,872

(22) Filed: Oct. 29, 2009

(51) Int. Cl. H03M 11/00

(52) U.S. Cl. 341/28

(57) ABSTRACT

A keyboard arrangement for an electronic device has multiple keys for inputting Chinese characters, multiple of the keys represent multiple combination vowels and all of the keys are arranged in a matrix form. The matrix of the keys are arranged in four key rows including a monosyllabic vowel row and three disyllabic vowel rows. The monosyllabic vowel row includes multiple keys arranged in a row and corresponding respectively to monosyllabic vowel phonetic symbols. Each disyllabic vowel row includes multiple keys arranged in a row and corresponding respectively to disyllabic vowel phonetic symbols those have a same transition vowel phonetic symbol and consonant phonetic symbols. The keys of the disyllabic vowel rows corresponding to a same monosyllabic vowel phonetic symbol are arranged in a column. Accordingly, an inputting method for Chinese characters applied with the keyboard arrangement is easy to learn and use.

### BACKGROUND OF THE INVENTION

1. Field of the Invention

The present invention relates to a keyboard arrangement, and more particularly to a keyboard arrangement for a phonetic symbol inputting method for Chinese characters.

2. Description of Related Art

Phonetic symbol inputting method for input Chinese characters are popularly used because phonetic symbols are well known and learned, especially in Taiwan. However, the conventional phonetic symbol inputting method has the drawbacks as follows:

1. All of phonetic symbols corresponding to a Chinese character have to be completely typed, so inputting speed of the conventional method is not rapid. In addition, the keyboard arrangement of the conventional phonetic symbols are broad and substantially comprises all of the character and numeral keys on the keyboard, so the inputting efficiency of the conventional inputting method is low. Furthermore, a user has to remember all of the locations of the keys corresponding to the phonetic symbols, but this is difficult to remember even someone invented a table for indicating the locations of the keys as shown in FIG. 10.

2. Because there are many different characters in Chinese have a same pronunciation and a same phonetic symbol combination, an input system always has an auto-choosing program to choose a correct one according to the inputted sentence or previous/subsequent characters. However, the conventional auto-choosing program always cannot choose a correct character even changes a correct character into a wrong one, so the conventional phonetic symbol inputting method is not convenient in use.

3. The phonetic systems for Chinese include two different systems, Taiwan phonetic symbol system and Romanization symbol system used in China. Although the pronunciations of the two phonetic systems are similar, Chinese character inputting systems for the two phonetic systems and the keyboard arrangements thereof are essentially different to each other. Therefore, to learn the inputting systems for the two phonetic systems is difficult.

To overcome the shortcomings, the present invention tends to provide a keyboard arrangement for phonetic symbol inputting method to mitigate or obviate the aforementioned problems.

### SUMMARY OF THE INVENTION

The main objective of the invention is to provide a keyboard arrangement for an electronic device that can improve the speed of inputting Chinese characters and is easy to learn and use. The keyboard arrangement for an electronic device comprises multiple keys for inputting Chinese characters with phonetic symbols. Multiple of the keys respectively represent multiple combination vowels each including one of transition vowel phonetic symbols of [symbol] and one of consonant phonetic symbols and monosyllabic vowel phonetic symbols to allow the keys corresponding to the combination vowels to input two phonetic symbols when the keys being pressed. The keys of the keyboard are arranged in a matrix form, wherein the keys corresponding to combination vowels having a same transition vowel phonetic symbol are arranged in a row.

Other objects, advantages and novel features of the invention will become more apparent from the following detailed description when taken in conjunction with the accompanying drawings.

### BRIEF DESCRIPTION OF THE DRAWINGS

FIG. 1A shows an embodiment of a keyboard arrangement in accordance with the present invention applied for a phonetic symbol system in Taiwan;

FIG. 1B shows an embodiment of a keyboard arrangement in accordance with the present invention applied for a Romanization phonetic symbol system in China;

FIG. 2 shows a second embodiment of a keyboard arrangement in accordance with the present invention;

FIG. 3 shows a third embodiment of a keyboard arrangement in accordance with the present invention;

FIG. 4 shows a fourth embodiment of a keyboard arrangement in accordance with the present invention;

FIG. 5 shows a fifth embodiment of a keyboard arrangement in accordance with the present invention;

FIGS. 6A and 6B show sixth embodiments of a keyboard arrangement in accordance with the present invention;

FIG. 7A-1 shows a first level of a seventh embodiment of a keyboard arrangement in accordance with the present invention;

FIG. 7A-2 shows a second level of the keyboard arrangement in FIG. 7A-1 after the key of “1” being pressed;

FIG. 7A-3 shows a second level of the keyboard arrangement in FIG. 7A-1 after the key of “2” being pressed;

FIG. 7B shows a table of keys referring to some phonetic symbols corresponding to the key of “2” on the keyboard arrangement in FIG. 7A-1;

FIG. 8A-1 shows the same keyboard arrangement as that in FIG. 7A-1;

FIG. 8A-2 shows a second level of the keyboard arrangement in FIG. 8A-1 after the key of “3” being pressed;

FIG. 8A-3 shows a third level of the keyboard arrangement in FIG. 8A-1 after the key of “1” in the second level being pressed;

FIG. 8B shows a table of keys referring to some phonetic symbols corresponding to the key of “3” on the keyboard arrangement in FIG. 8A-1;

FIG. 9 shows a block diagram of an inputting method applied with a keyboard arrangement in accordance with the present invention; and

FIG. 10 shows a table for indicating the locations of the keys referring to combination vowels for a conventional keyboard arrangement for inputting Chinese characters.

### DETAILED DESCRIPTION OF PREFERRED EMBODIMENT

Phonetic symbols corresponding to a Chinese character comprise consonants and vowels, wherein the vowels include monosyllabic vowels and disyllabic vowels. The consonants include phonetic symbols of [symbol] [symbol] [symbol] The monosyllabic vowels include phonetic symbols of [symbol] (ê), [symbol] (ei), [symbol] (ai), [symbol] (an), [symbol] (en), [symbol] (eng), [symbol] (ao), [symbol] (ang), [symbol] (a), [symbol] (ou), [symbol] (o), [symbol] (e)”, wherein the symbols in brackets are phonetic symbols of Romanization corresponding to the phonetic symbol used in Taiwan. Each disyllabic vowel is combined by a transition vowel including phonetic symbols of [symbol] and one of the monosyllabic vowel. The disyllabic vowel having a transition vowel phonetic symbol of “-” includes [symbol] (ia ya), [symbol] (ie ye), [symbol] (iao yao), [symbol] (iou you), [symbol] (ian yan), [symbol] (in yin), [symbol] (iang yang), [symbol] (ing ying), [symbol] (yai), [symbol] (yo)”. The disyllabic vowel having a transition vowel phonetic symbol of [symbol] includes [symbol] (ua wa), [symbol] (uo wo), [symbol] (uai wai), [symbol] (uei wei), [symbol] (uan wan), [symbol] (uen wen), [symbol] (uang wang), [symbol] (ong weng)”. The disyllabic vowel having a transition vowel phonetic symbol of [symbol] includes [symbol] (üe yue), [symbol] (üan yuan), [symbol] (ün yun), [symbol] (iong yong)”. Additionally, a disyllabic consonant is defined be a combination of one of the consonant phonetic symbols and one of the transition consonant phonetic symbols, such as [symbol] and so on. A combination vowel is defined to be one of the disyllabic consonants and the disyllabic vowels.

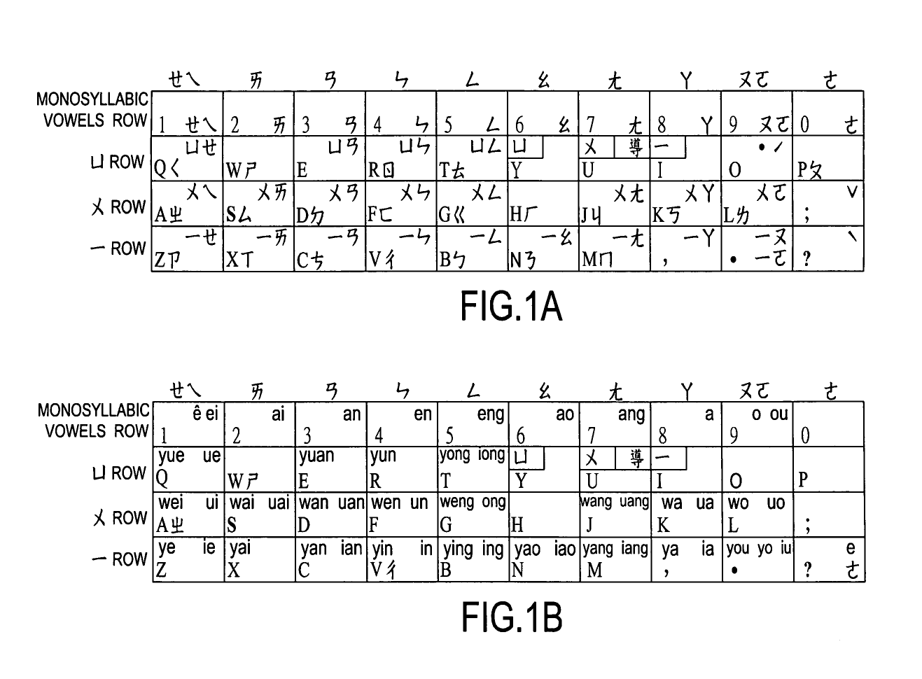

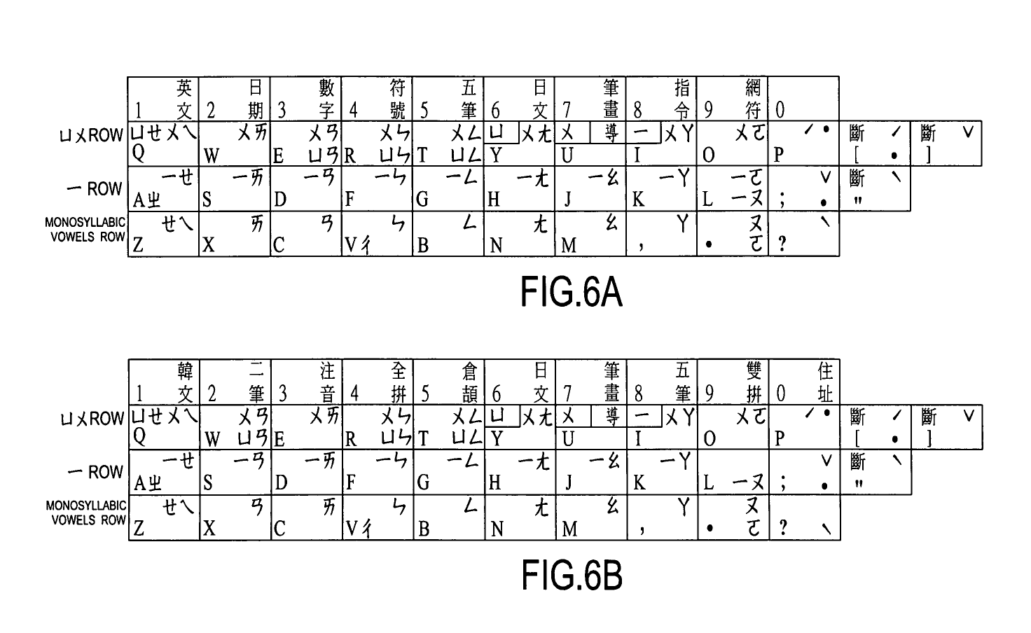

With reference to FIGS. 1A and 1B, a first embodiment of a keyboard arrangement in accordance with the present invention comprises multiple keys arranged in a matrix form including four key rows including one monosyllabic vowel row and three disyllabic vowel rows. The monosyllabic vowel row includes multiple keys arranged in a row and corresponding respectively to the phonetic symbols of monosyllabic vowels. Each disyllabic vowel row includes multiple keys arranged in a row and corresponding respectively to the disyllabic vowel those have a same transition vowel phonetic symbol, such that each key of the disyllabic vowel row represents two phonetic symbols. The keys of the vowel rows corresponding to a same monosyllabic vowel phonetic symbol are arranged in a column. In the first embodiment, the keys of the monosyllabic vowel row are arranged on the row of the numeral keys on the keyboard. The phonetic symbols of monosyllabic vowels of [symbol] (ei)” are arranged in the numeral key of “1”, the monosyllabic vowel phonetic symbols of [symbol] (an), [symbol] (en), [symbol] (eng), [symbol] (ao), [symbol] (ang), [symbol] (a)” are arranged respectively in the numeral keys of “2” to “8”, the monosyllabic vowel phonetic symbols of [symbol] (ou), [symbol] (o)” are arranged in the numeral key of “9” and the monosyllabic vowel phonetic symbol of [symbol] (e)” is arranged in the numeral key of “0”. In an alternative embodiment, the monosyllabic vowel phonetic symbols can be arranged in sequence as shown in FIG. 4.

The keys of the disyllabic vowel row corresponding to the transition vowel phonetic symbol of [symbol] are arranged on the upper character row of the keyboard, i.e. “Q, W, P” row. With the keys of the monosyllabic vowel rows corresponding to a same monosyllabic vowel phonetic symbol are arranged in a column, such that the key of “Q” corresponding to the numeral key of “1” refers to the disyllabic vowel phonetic symbol of [symbol] (yue, ue)” that corresponds to a monosyllabic vowel phonetic symbol of [symbol] (ê)” (there is not a disyllabic vowel phonetic symbol of [symbol] in Chinese). The key of “W” corresponding to the numeral key of “2” refers to the disyllabic vowel phonetic symbol of [symbol] (wai, uai)” that corresponds to a monosyllabic vowel phonetic symbol of [symbol] (ai)” and so on. In this row, the keys corresponding to the transition vowel phonetic symbols of [symbol] are arranged respectively on the keys of the disyllabic vowel row corresponding to the transition vowel phonetic symbol of [symbol] and respectively at columns corresponding to the vowel phonetic symbols of [symbol] (ao), [symbol] (ang), [symbol] (a)” because there are not disyllabic vowel phonetic symbols of [symbol] and the transition vowel phonetic symbols of [symbol] can serve as monosyllabic vowel phonetic symbol, respectively. In this embodiment, the keys corresponding to the transition vowel phonetic symbols of [symbol] are arranged on the keys of “Y, U, I”.

The keys of the disyllabic vowel row corresponding to the transition vowel phonetic symbol of [symbol] are arranged on the middle character row of the keyboard, i.e. “A, S, D, . . . , L” row. Accordingly, the key of “A” corresponding to the numeral key of “1” refers to the two phonetic symbols of the disyllabic vowel of [symbol] (uei weir that corresponds to a monosyllabic vowel phonetic symbol of [symbol] (ei)” (there is not a disyllabic vowel of [symbol] in Chinese), the key of “S” corresponding to the numeral key of “2” refers to the two phonetic symbols of the disyllabic vowel of [symbol] (uai wai)” that corresponds to a monosyllabic vowel phonetic symbol of [symbol] (ai)” and so on.

The keys of the disyllabic vowel row corresponding to the transition vowel phonetic symbol of “-” are arranged on the lower character row of the keyboard, i.e. “Z, X, C, . . . , ?” row. Accordingly, the key of “Z” corresponding to the numeral key of “1” refers to the disyllabic vowel phonetic symbols [symbol] (ie ye)” that corresponds to a monosyllabic vowel phonetic symbol of [symbol] (ê)” (there is not a disyllabic vowel phonetic symbol of [symbol] in Chinese), the key of “X” corresponding to the numeral key of “2” refers to the disyllabic vowel phonetic symbols of [symbol] (yap” that corresponds to a monosyllabic vowel phonetic symbol of [symbol] (ai)” and so on.

With the matrix arrangement of the keyboard in accordance with the keys of the monosyllabic vowel rows corresponding to a same monosyllabic vowel phonetic symbol are arranged in a column, a user can easily find the location of a key corresponding to a disyllabic vowel phonetic symbol based on the location of the key referring to a same monosyllabic vowel phonetic symbol.

In addition, with reference to FIG. 4, the rows corresponding to the transition vowel phonetic symbols of [symbol] can be arranged respectively on the character rows of the keyboard at any desired sequence. For example, the keys of the disyllabic vowel row corresponding to the transition vowel phonetic symbol of “-” are arranged on the upper character row, the keys of the disyllabic vowel row corresponding to the transition vowel phonetic symbol of [symbol] are arranged on the middle character row of the keyboard, and the keys of the disyllabic vowel row corresponding to the transition vowel phonetic symbol of [symbol] are arranged on the lower character row of the keyboard.

Accordingly, when a key corresponding to one of the disyllabic vowel phonetic symbols is pressed, a corresponding disyllabic vowel including two phonetic symbols is simultaneously input. For example, in the first embodiment to input characters pronounced by [symbol] only two keys of “V, A” have to be pressed. Thus, to input complete phonetic symbols for a Chinese character is unnecessary, and the inputting speed for Chinese is rapid.

The consonant phonetic symbols of [symbol] [symbol] [symbol] are arranged on the keys of the disyllabic vowel phonetic symbols. In the first embodiment, the consonant phonetic symbols of [symbol] are arranged on the upper character row and may be respectively on the keys of “Q, W, R, T, P”, the consonant phonetic symbols of [symbol] [symbol] are arranged on the middle character row and may be respectively on the keys of “A, S, D, F, G, H, J, K, L”, and the consonant phonetic symbols of [symbol] are arranged on the lower character row and may be respectively on the keys of “Z, X, C, V, B, N, M”. To identify the inputs of consonant phonetic symbols or the disyllabic vowel phonetic symbols, a guiding key is arranged on the key of [symbol] When the guiding key is pressed firstly, a corresponding consonant character is inputted when a corresponding key is then pressed. For example, when the key of “U” is pressed and a key of “A” is then pressed, the corresponding consonant character corresponding to the phonetic symbol of [symbol] is inputted but not the disyllabic vowel character corresponding to the phonetic symbol of [symbol] (uei wei)”. Contrary, when the key of “A” is individually pressed, the disyllabic vowel character corresponding to the phonetic symbol of [symbol] (uei wei)” is inputted.

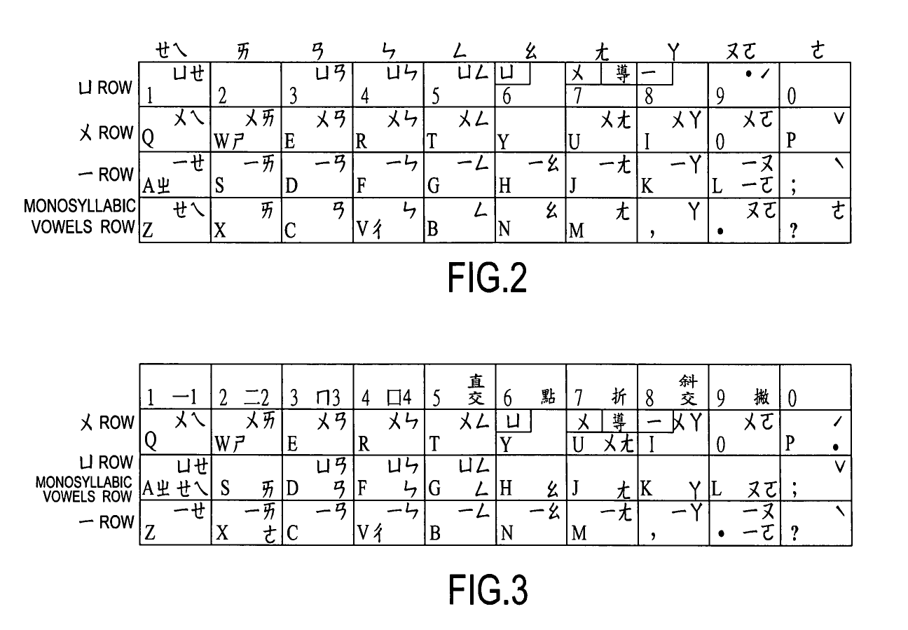

With such an arrangement, a user does not have to remember all of the locations of the keys corresponding to all of the phonetic symbols, the keyboard arrangement in accordance with the present invention is easily learned and used. In an alternative embodiment as shown in FIG. 2, the keys of the monosyllabic vowel row are arranged on the lower character row of the keyboard, i.e. “Z, X, C, . . . , ?” row, the keys of the disyllabic vowel rows corresponding to the transition vowel phonetic symbols of [symbol] are arranged on the row of the numeral keys, the upper character row and the middle character row of the keyboard.

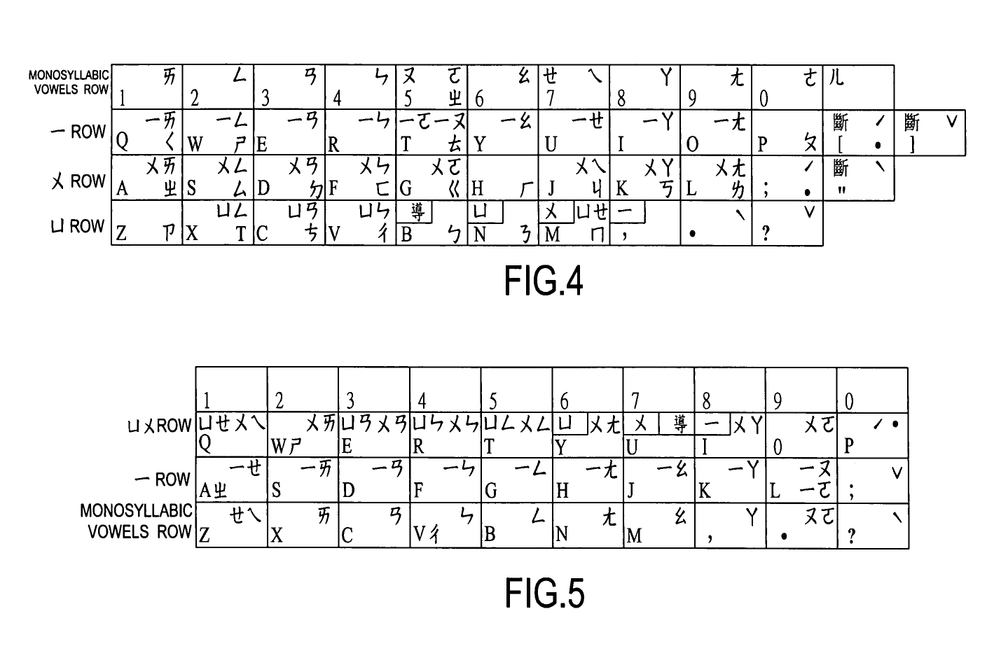

In another alternative embodiment as shown in FIG. 3, the keys of the monosyllabic vowel row are arranged on a same row as the keys of the disyllabic vowel row having the transition vowel phonetic symbol of [symbol] In this embodiment, multiple stroke element keys are arranged on the numeral keys of “1 to 0” and correspond respectively to the strokes of Chinese characters including [symbol] When a stroke element key is pressed before or after pressing key(s) corresponding to the vowel phonetic symbol(s)/consonant phonetic symbol, a Chinese character having both of the inputted stroke and vowel phonetic symbol(s)/consonant phonetic symbol is inputted. Consequently, the numbers of characters having the same features are much less than those having only one of features, so the correction of inputting a Chinese character is improved.

Furthermore, with reference to FIG. 4 three tone keys are arranged on the keys in a column corresponding to the key of the monosyllabic vowel phonetic symbol of [symbol] (e)”. In this embodiment, the tone keys are arranged respectively on the keys of “[”, “]”, “;” and “'”. With pressing one of the tone keys after a key corresponding to a vowel phonetic symbol is pressed, characters having the inputted vowel phonetic symbol with the tone are shown and the amount of such characters are less than that only having an inputted vowel phonetic symbol. In addition, at least one phrase determining key can be arranged on the keyboard on the keys of symbols of “[”, “]” or “'”. In the preferred embodiment, three phrase determining keys are arranged on the keyboard and are incorporated respectively with a tone. With pressing one of the phrase determining keys, a phrase incorporated by two characters with a first character having a previously pressed vowel phonetic symbol and a second character having an instantly pressed vowel phonetic symbol is inputted.

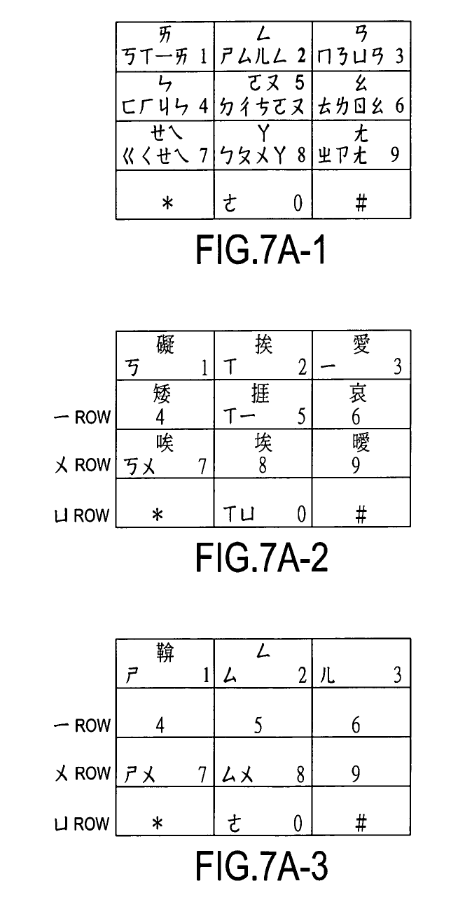

In a further alternative embodiment as shown in FIG. 5, the keys of the disyllabic vowel row having the transition vowel phonetic symbol of [symbol] are arranged on a same row as the keys of the disyllabic vowel row having the transition vowel phonetic symbol of [symbol] In this embodiment, a guiding key can be arranged on the key of [symbol] With the arrangement of the guiding key, the disyllabic vowel phonetic symbol of [symbol] or [symbol] being inputted can be efficiently identified when a corresponding key is pressed. Accordingly, area of the keyboard arrangement is reduced, and the speed of typing based on the keyboard arrangement in accordance with the present invention can be enhanced.

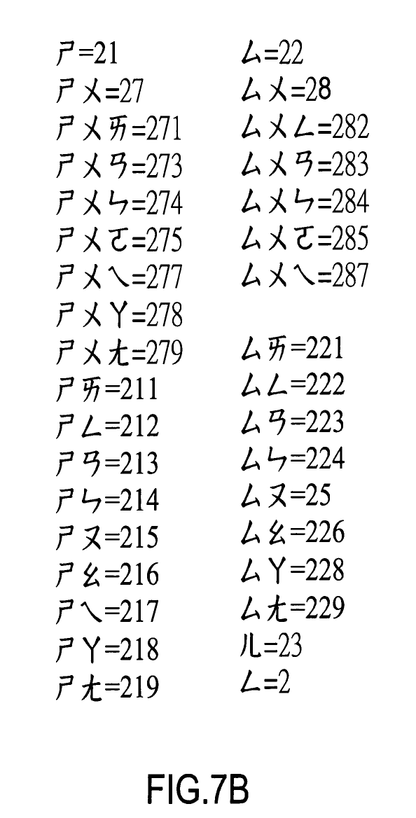

With reference to FIG. 6A, multiple transferring keys are arranged on the numeral keys of “1 to 0” and correspond respectively to transferring functions to shift the keys into different modes for inputting English, dates, numbers, symbols, Chinese by Wubizixing inputting method, Japanese, Chinese by Strokes method, commands or Web symbols. With reference to FIG. 6B, the transferring keys arranged on the numeral keys of “1 to 0” may correspond respectively to input Korean, Chinese by Two Strokes inputting method, Chinese by Phonetic symbol inputting method, Chinese by conventional Phonetic symbol inputting method, Chinese by Cangjie inputting method, Japanese, Strokes, Chinese by Wubizixing inputting method, Chinese by two Phonetic symbols inputting method and addresses. When one of the transferring keys is pressed, the keyboard is transferred for inputting corresponding language, characters or symbols.

With such a keyboard arrangement in accordance with the present invention, the key arrangements of the phonetic systems in Taiwan and China are the same. Accordingly, to learn and use the inputting systems for the two phonetic systems is easy and convenient.

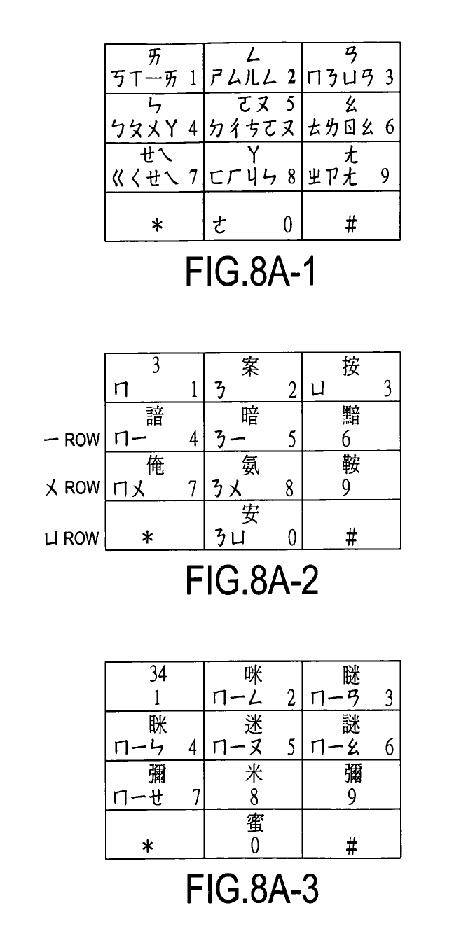

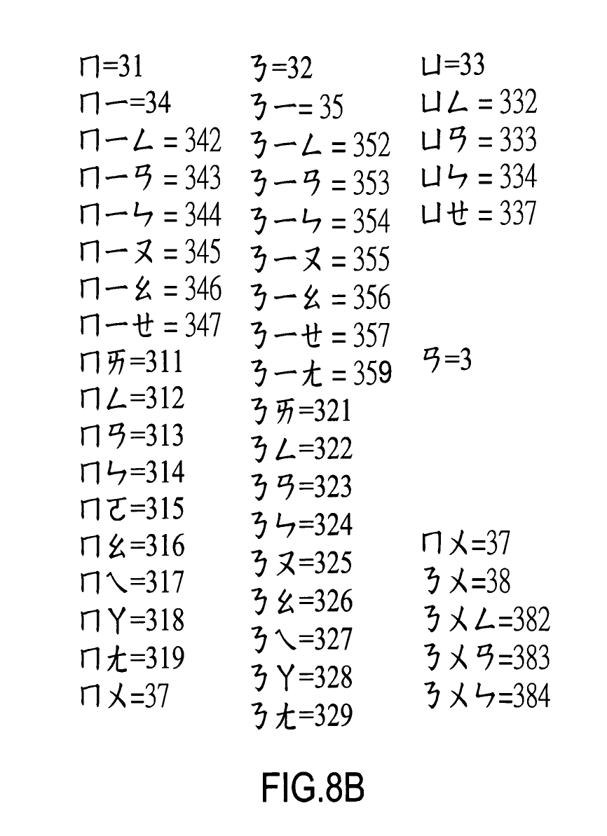

With reference to FIGS. 7 and 8, the keyboard arrangement in accordance with the present invention can be arranged on in a 4×3 matrix. Accordingly, the keyboard arrangement can be applied on an electronic device having a matrix numeral keyboard arrangement from 1 to 0, such as computer or a cell phone or the like. In this embodiment, the keyboard arrangement has three levels. In the first level, the keys refer respectively to at least one vowel phonetic symbol incorporated with multiple consonant phonetic symbols. In the preferred embodiment, the vowel phonetic symbols of [symbol] are arranged on the first row, the vowel phonetic symbols of [symbol] are arranged on the second row, the vowel phonetic symbols of [symbol] are arranged on the third row, and the vowel phonetic symbol of [symbol] is arranged on the fourth row. In the first row, the key of “1” refers to the vowel phonetic symbol of [symbol] with the consonant/transition vowel phonetic symbols of [symbol] the key of “2” refers to vowel phonetic symbols of [symbol] with the consonant phonetic symbols of [symbol] and the key of “3” refers to the vowel phonetic symbol of” [symbol] with the consonant/transition vowel phonetic symbols of [symbol] In the second row, the key of “4” refers to the vowel phonetic symbol of [symbol] with the consonant phonetic symbols of [symbol] the key of “5” refers to vowel phonetic symbols of [symbol] with the consonant phonetic symbols of [symbol] and the key of “6” refers to the vowel phonetic symbol of [symbol] with the consonant phonetic symbols of [symbol] In the third row, the key of “7” refers to the vowel phonetic symbols of [symbol] with the consonant phonetic symbols of [symbol] the key of “8” refers to vowel phonetic symbols of [symbol] with the consonant/transition vowel phonetic symbols of [symbol] and the key of “9” refers to the vowel phonetic symbol of [symbol] with the consonant phonetic symbols of [symbol] In the fourth row, the key of “0” refers to the vowel phonetic symbol of [symbol] The vowel phonetic symbol(s) referring to a key has a priority to the consonant phonetic symbols on the same key.

In the second level, the keys on the first row refer respectively to the consonants and the transition vowels on a corresponding pressed key. For example, when the key of “1” is pressed, the keys on the first row on the second level refer respectively to the consonant phonetic symbols of [symbol] referring to the key of “1” as shown in FIG. 7A-2. On the second level, the second, third and fourth rows refer respectively to the disyllabic consonants having the transition vowel phonetic symbols of [symbol] such as [symbol] or [symbol] [symbol] FIGS. 7A-3 and 8A-2 show the second level of the keyboard arrangement when the key of “2” or “3” is pressed.

In the third level, the keys refer respectively to the vowel phonetic symbols arranged as those in the first level. FIG. 8A-3 shows the third level of the keyboard arrangement when the key of “3” is pressed.

In operation, when a key is pressed, the keyboard arrangement skips into a next level for further inputting. With reference to FIGS. 7B and 8B, tables of corresponding keys referring to some phonetic symbols are shown. For example, to input a character referring to the phonetic symbols of [symbol] the keys of “2’,“7? and “4” are pressed in sequence. In the first and second levels, the key of the symbol of “#” refers to an electing key. When the electing key is pressed, the symbol referring to the previously pressed is inputted. For example, when the key of “1” is pressed and the electing key is then pressed, the vowel phonetic symbol of [symbol] is inputted. If a user presses the key of “1” in the first level, then presses the key of “5” and finally presses the electing key, the disyllabic consonant phonetic symbol of “ [symbol] ” is inputted.

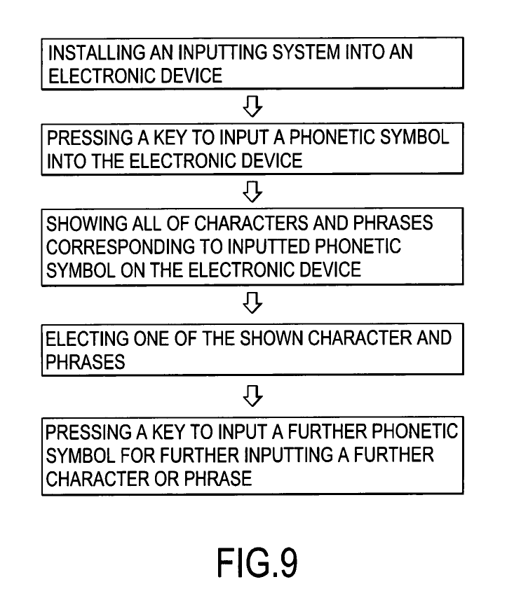

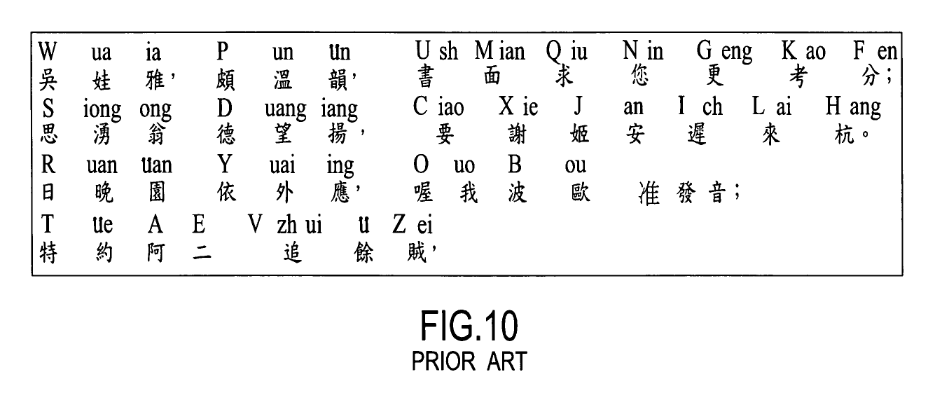

With reference to FIG. 9, an inputting method incorporating with the keyboard arrangement in accordance with the present invention comprising steps of

(a) installing an inputting system into an electronic device, such as a computer, a cell phone or the like having a keyboard with a keyboard arrangement in accordance with the present invention;

(b) pressing a key to input a phonetic symbol into the electronic device, wherein the combination vowel characters including disyllabic vowel/consonant phonetic symbols have a priority to the consonant phonetic symbols;

(c) showing all of characters and phrases selected from a database and corresponding to inputted phonetic symbol on the electronic device;

(d) electing one of the shown characters and phrases; and

(e) pressing a key to input a further phonetic symbol for further inputting a further character or phrase.

In the step (b), with the keyboard arrangement in accordance with the present invention, when a key corresponding to a disyllabic vowel phonetic symbol is pressed, characters corresponding to the inputted disyllabic vowel phonetic symbol are shown. If the key corresponding to a disyllabic vowel phonetic symbol also corresponds to a consonant phonetic symbol is pressed, the characters and phrases corresponding to the disyllabic vowel phonetic symbol have a priority to the characters and phrases corresponding to the consonant phonetic symbol. For example, the key of “B” corresponding simultaneously to the disyllabic vowel phonetic symbol of [symbol] and the consonant phonetic symbol of [symbol] the characters corresponding to the disyllabic vowel phonetic symbol of [symbol] are listed before the characters corresponding to the consonant phonetic symbol of [symbol] If a user wants to input a character having a consonant phonetic symbol but not a disyllabic vowel phonetic symbol, the key being pressed twice or a guiding key being pressed before/after pressing the key can be applied. Alternatively, the inputting system may comprise a database that comprises multiple characters and phrases encoding by a phonetic symbol system and the characters and phrases corresponding to combination vowel phonetic symbols have a priority to the characters and phrases corresponding to consonant phonetic symbols. When a user presses a key that corresponds to at least one disyllabic vowel phonetic symbol and consonant phonetic symbol, the characters and phrases corresponding to the disyllabic vowel phonetic symbol(s) and consonant phonetic symbol(s) and encoded by the priority of the disyllabic vowel phonetic symbol are elected and shown in the step (c).

In the step (d), this step is optional and can be skipped. If a user does not elect a desired character, the character firstly listed is automatically inputted.

In the step (e), when a subsequent key is pressed, characters referring to the corresponding disyllabic vowel phonetic symbol, monosyllabic vowel phonetic symbol or consonant phonetic symbol are shown. In addition, the phrases having the previously and instantly inputted vowel phonetic symbols or consonant phonetic symbols are shown to allow the user to elect. Wherein, the phrases have a sequence that the phrases corresponding to the disyllabic vowel phonetic symbol have a priority to the phrases corresponding to the consonant phonetic symbol. This means that the phrases corresponding to the disyllabic vowel phonetic symbol are listed before the phrases corresponding to the consonant phonetic symbol. If the user does not elect a desired character or phrase and further presses a key, a phrase listed on the first position is inputted and the previously inputted character may be replaced. For example, after a key corresponding to the disyllabic vowel phonetic symbol of [symbol] being pressed, a key corresponding to the disyllabic vowel phonetic symbol of [symbol] is then pressed and a phrase having the vowel phonetic symbols of [symbol] are shown. In addition, if a key corresponding simultaneously to a disyllabic vowel phonetic symbol and a consonant phonetic symbol is pressed and a key corresponding to a monosyllabic vowel phonetic symbol is then pressed, the previously inputted symbol can be determined to a consonant phonetic symbol but not a disyllabic vowel phonetic symbol. For example, when a key of “M” corresponding to the disyllabic vowel phonetic symbol of [symbol] and consonant phonetic symbol of [symbol] is pressed and a key of “4” corresponding to the monosyllabic vowel phonetic symbol of [symbol] is then pressed, the first inputted key can be referred to the consonant phonetic symbol of [symbol] but not the disyllabic vowel phonetic symbol of [symbol] To determine the pressed key to be referred to a corresponding disyllabic vowel phonetic symbol or consonant phonetic symbol is that whether a phrase can be combined by the symbol corresponding to a previously or subsequently pressed key with that corresponding to the instantly pressed key or not. If such a phrase exists, the phrase has a priority to the individual symbols corresponding respectively to the two inputted keys.

To input a phrase having two characters, keys corresponding to the consonant phonetic symbol of the first character, the disyllabic/monosyllabic vowel phonetic symbol of the first character, the consonant phonetic symbol of the second character and the disyllabic/monosyllabic vowel phonetic symbol of the second character are pressed in sequence. In a simplified embodiment, two keys corresponding to the disyllabic/monosyllabic vowel phonetic symbol of the first character and the disyllabic/monosyllabic vowel phonetic symbol of the second character are pressed.

To input a phrase having three or more characters, the consonant phonetic symbol of the first character, the disyllabic/monosyllabic vowel phonetic symbol of the first character, the disyllabic/monosyllabic vowel phonetic symbol of the second character and the disyllabic/monosyllabic vowel phonetic symbol of the last character are pressed in sequence. In a simplified embodiment, keys corresponding to the disyllabic/monosyllabic vowel phonetic symbols of the first, the second and the last characters are pressed. The phrase corresponding to the inputted symbols are listed to allow the user to elect. If the user does not elect one, the firstly listed one is automatically inputted.

For example, if a user wants to input a sentence of [symbol] [symbol] [symbol] the keys is pressed in sequence as follows: [symbol] [symbol] [symbol] [symbol] [symbol] [symbol] [symbol] [symbol] [symbol] [symbol] Accordingly, to input the whole phonetic symbols is unnecessary, so the necessary strikes for inputting Chinese character can be efficiently reduced and the speed of inputting Chinese is improved and rapid.

With the phrase determining key being pressed following an instantly pressed key, a phrase having the previously and instantly inputted disyllabic/monosyllabic vowel phonetic symbols are determined to prevent the system automatically from determining the phrase by the instantly inputted vowel phonetic symbol with the subsequently inputted vowel phonetic symbol. With the arrangement of the phrase determining key, the correction of inputting a sentence is increased.

In addition, with the phrase determining key being pressed following an instantly pressed key as shown in FIGS. 4 and 6, a phrase having the previously and instantly inputted disyllabic/monosyllabic vowel phonetic symbols are determined to prevent the system automatically from determining the phrase by the instantly inputted vowel phonetic symbol with the subsequently inputted vowel phonetic symbol. With the arrangement of the phrase determining key, the correction of inputting a sentence is increased.

The keyboard arrangement and inputting method in accordance with the present invention has the following advantages.

(a) The keyboard arrangement in accordance with the present invention is easy to learn and remember.

(b) The keyboard arrangement can be applied both to the phonetic symbols systems in Taiwan and China and can efficiently combine these two different systems together.

(c) The keyboard arrangement can provide more information to an input system, so amounts of the characters and phrases with the same features can be reduced. Accordingly, a phrase or sentence can be correctly inputted with less strikes, such that the speed of inputting Chinese character is rapid.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A keyboard arrangement for an electronic device comprising multiple keys for inputting Chinese characters, wherein the keys are arranged in a matrix form, multiple of keys respectively represent multiple combination vowels each including one of transition vowel phonetic symbols of [symbol] to allow the keys corresponding to the combination vowels to input two phonetic symbols including one of the transition vowel phonetic symbols when the keys being pressed, and the keys corresponding to combination vowels having a same transition vowel phonetic symbol are arranged in a row.

2. The keyboard arrangement as claimed in claim 1, wherein the matrix of the keys has four key rows including a monosyllabic vowel row and three disyllabic vowel rows;
the monosyllabic vowel row includes multiple keys arranged in a row and corresponding respectively to monosyllabic vowel phonetic symbols;
each disyllabic vowel row includes multiple keys arranged in a row and corresponding respectively to disyllabic vowel phonetic symbols those have a same transition vowel phonetic symbol; and
the keys of the disyllabic vowel rows corresponding to a same monosyllabic vowel phonetic symbol are arranged in a column.

3. The keyboard arrangement as claimed in claim 2, wherein the monosyllabic vowel phonetic symbol of [symbol] (ê), [symbol] (ei)” are arranged in a same key, the monosyllabic vowel phonetic symbols of [symbol] (ai), [symbol] (an), [symbol] (en), [symbol] (eng), [symbol] (ao), [symbol] (ang), [symbol] (a), [symbol] (e)” are arranged respectively in different keys, the monosyllabic vowel phonetic symbols of [symbol] (ou), [symbol] (o)” are arranged in a same key.

4. The keyboard arrangement as claimed in claim 3, wherein the keys of the monosyllabic vowel row are arranged on the row of the numeral keys on the keyboard.

5. The keyboard arrangement as claimed in claim 4, wherein the monosyllabic vowel phonetic symbol of [symbol] (ê), [symbol] (ei)” are arranged in the numeral key of “1”, the monosyllabic vowel phonetic symbols of [symbol] (ai), [symbol] (an), [symbol] (en), [symbol] (eng), [symbol] (ao), [symbol] (ang), [symbol] (a)” are arranged respectively in the numeral keys of “2” to “8”, the monosyllabic vowel phonetic symbols of [symbol] (ou), [symbol] (o)” are arranged in the numeral key of “9” and the monosyllabic vowel phonetic symbol of [symbol] (e)” is arranged in the numeral key of “0”.

6. The keyboard arrangement as claimed in claim 5, wherein
the keys of the disyllabic vowel row corresponding to the transition vowel phonetic symbol of [symbol] are arranged on the upper character row of the keyboard, i.e. “Q, W, E, . . . , P” row;
the keys of the disyllabic vowel row corresponding to the transition vowel phonetic symbol of [symbol] are arranged on the middle character row of the keyboard, i.e. “A, S, D, . . . , L” row;
the keys of the disyllabic vowel row corresponding to the transition vowel phonetic symbol of “-” are arranged on the lower character row of the keyboard, i.e. “Z, X, C, . . . , ?” row; and
the keys corresponding to the transition vowel phonetic symbols of [symbol] [symbol] are arranged respectively on the keys of the disyllabic vowel row corresponding to the transition vowel phonetic symbol of [symbol] and respectively at columns corresponding to the vowel phonetic symbols of [symbol] (ao), [symbol] (ang), [symbol] (a)”.

7. The keyboard arrangement as claimed in claim 6, wherein
the consonant phonetic symbols of [symbol] are arranged on the upper character row and respectively on the keys of “Q, W, R, T, P”;
the consonant phonetic symbols of [symbol] are arranged on the middle character row and respectively on the keys of “A, S, D, F, G, H, J, K, L”; and
the consonant phonetic symbols of [symbol] are arranged on the lower character row and respectively on the keys of “Z, X, C, V, B, N, M”.

8. The keyboard arrangement as claimed in claim 2 further comprising a guiding key for identifying the inputs of consonant phonetic symbols or the disyllabic vowel phonetic symbols.

9. The keyboard arrangement as claimed in claim 8, wherein the guiding key is on the same key of

[symbol]

10. The keyboard arrangement as claimed in claim 2, wherein the keys of the monosyllabic vowel row are arranged on a same row as the keys of the disyllabic vowel row having the transition vowel phonetic symbol of

[symbol]

11. The keyboard arrangement as claimed in claim 10 further comprising multiple stroke element keys arranged in a row and corresponding respectively to strokes of Chinese characters including

[symbol]

12. The keyboard arrangement as claimed in claim 10 further comprising multiple transferring keys arranged in a row and corresponding respectively to transferring functions to shift the keys into different modes.

13. The keyboard arrangement as claimed in claim 2 further comprising three tone keys arranged on the keys in a column corresponding to the key of the monosyllabic vowel phonetic symbol of [symbol] (e)”.

14. The keyboard arrangement as claimed in claim 2 further comprising at least one phrase determining key arranged on the keyboard on at least one of the keys of symbols of “[”, “]” and “'”.

15. The keyboard arrangement as claimed in claim 2, wherein the keys of the disyllabic vowel row having the transition vowel phonetic symbol of [symbol] are arranged on a same row as the keys of the disyllabic vowel row having the transition vowel phonetic symbol of

[symbol]

16. The keyboard arrangement as claimed in claim 2, wherein
the keys of the monosyllabic vowel row are arranged on the lower character row of the keyboard, i.e. “Z, X, C, . . . , ?” row;
the keys of the disyllabic vowel rows corresponding to the transition vowel phonetic symbols of [symbol] are arranged on the row of the numeral keys, the upper character row and the middle character row of the keyboard.

17. The keyboard arrangement as claimed in claim 1, wherein keys of the keyboard arrangement are arranged on in a 4×3 matrix and have multiple levels.

18. The keyboard arrangement as claimed in claim 17, wherein keys corresponding to disyllabic consonant phonetic symbols those have a same transition vowel phonetic symbol and are arranged in a row are arranged in a second level.

19. An inputting method incorporating with the keyboard arrangement as claimed in claim 1 comprising steps of
(a) installing an inputting system into an electronic device having a keyboard with a keyboard arrangement in claim 1, wherein the inputting system further comprise a database that comprises multiple characters and phrases encoding by a phonetic symbol system and the characters and phrases corresponding to combination vowel phonetic symbols have a priority to the characters and phrases corresponding to consonant phonetic symbols;
(b) pressing a key to input a phonetic symbol into the electronic device;
(c) showing all of characters and phrases selected from the database and corresponding to inputted phonetic symbol on the electronic device; and
(d) pressing a key to input a further phonetic symbol for further inputting a further character or phrase.

20. The method as claimed in claim 19 further comprising a step of electing one of the shown character and phrases after the step (c).

21. The method as claimed in claim 19, wherein the characters and phrases corresponding to disyllabic vowel phonetic symbol have a priority to the characters and phrases corresponding to the consonant phonetic symbol.

22. The method as claimed in claim 21, wherein when a subsequent key is pressed in the step (d), phrases having the previously and instantly inputted vowel phonetic symbols or consonant phonetic symbols are shown for electing, wherein the phrases have a sequence that the phrases corresponding to the disyllabic vowel phonetic symbol have a priority to the phrases corresponding to the consonant phonetic symbol; and
a phrase listed on the first position is inputted when a key is further pressed.

23. The method as claimed in claim 19, wherein a key corresponding simultaneously to a disyllabic vowel phonetic symbol and a consonant phonetic symbol is pressed and a key corresponding to a monosyllabic vowel phonetic symbol is then pressed, the previously inputted symbol is determined to the consonant phonetic symbol.

24. The method as claimed in claim 19, wherein keys corresponding to a consonant phonetic symbol of a first character, a disyllabic/monosyllabic vowel phonetic symbol of a first character, a consonant phonetic symbol of a second character and a disyllabic/monosyllabic vowel phonetic symbol of a second character are pressed in sequence to input a phrase having two characters.

25. The method as claimed in claim 19, wherein a consonant phonetic symbol of a first character, a disyllabic/monosyllabic vowel phonetic symbol of a first character, a disyllabic/monosyllabic vowel phonetic symbol of a second character and a disyllabic/monosyllabic vowel phonetic symbol of a last character are pressed in sequence to input a phrase having more than two characters.

26. The method as claimed in claim 19 further comprising a step of pressing a guiding key before pressing a key referring to a consonant phonetic symbol and a disyllabic vowel phonetic symbol to input a character having the consonant phonetic symbol.

27. The method as claimed in claim 19 further comprising a step of pressing a guiding key after pressing a key referring to a consonant phonetic symbol and a disyllabic vowel phonetic symbol to input a character having the consonant phonetic symbol.

28. The method as claimed in claim 19 further comprising a step of twice pressing a key referring to a consonant phonetic symbol and a disyllabic vowel phonetic symbol to input a character having the consonant phonetic symbol.
